(19) United States
(12) Patent Application Publication
(10) Pub. No.: US 2004/0185280 A1
(43) Pub. Date: Sep. 23, 2004

(54) Heat-resistant insulating film and insulating method

(75) Inventors: Toshimasa Hangai, Yamagata-ken (JP); Hisao Mitsuhashi, Yamagata-ken (JP)

Correspondence Address: MCGINN & GIBB, PLLC, 8321 OLD COURTHOUSE ROAD, SUITE 200, VIENNA, VA, 22182-3817, US

(73) Assignees: Pioneer Corporation, Tokyo (JP); Tohoku Pioneer Corporation, Tendo-shi (JP)

(21) Appl. No.: 10/797,076

(22) Filed: Mar. 11, 2004

(30) Foreign Application Priority Data
Mar. 17, 2003 (JP) 2003-71446

(51) Int. Cl. H01L 23/495

(52) U.S. Cl. 428/473.5

(57) ABSTRACT

In order to fit a heat-resistant insulating film onto a circuit board mounted with electronic components, the heat-resistant insulating film is three-dimensionally formed into a pattern profile corresponding to that of a surface to be insulated including concave or convex portion, and then covers the electronic components or the circuit board. This insulation of the surface to be insulated by fitting the insulating film with functionality such as heat resistance enables easy insulation without waste.

### BACKGROUND OF THE INVENTION

1. Field of the Invention

The present invention relates to a heat-resistant insulating film and to a method for insulating utilizing the same film.

The present application claims priority from Japanese Patent Application No. 2003-71446, the disclosure of which is incorporated herein by reference.

2. Description of the Related Art

Advancement in packing densities and functionality turns the spotlight on functionality of an insulating layer formed on electronic components or on a circuit board mounted with electronic components. Instead of thermosetting resins such as epoxy resins conventionally used as an insulating film, polyimide resins have come into use, because the polyimide resins have high heat resistance, mechanical strength, and dimensional stability. Generally, formation of an insulating layer made of such a polyimide resin includes: applying a precursor solution in a predetermined thickness to a surface to be insulated, and then subjecting them to dehydration cyclization imide conversion by drying and heating, thereby forming a predetermined thick layer of a resin on the surface to be insulated. This formation is disclosed, for example, in the paragraph 0037 of JP 07-45919 A.

However, there are some problems associated with this formation of the insulating layer, i.e., the complicated process of the formation, the high cost of the formation, and lack of manufacturability. Further, another problem arises in the case where the surface to be insulated has concave or convex portions. That is, the resin must be applied to level the concave or convex portions. This signifies excessive use of an insulating material, increasing the weight of an object to be insulated.

On the other hand, it is also considered that a thin layer of insulating film is attached on the surface to be insulated. However, a thin film of a typical polyimide resin with high functionality is not compliant with a profile of a surface. Accordingly, when the surface to be insulated has concave or convex portions, fine attachment is impossible, resulting in lack of stability after attachment. Moreover, when the surface to be insulated has a complicated profile, a combination of several sheets of film should be utilized, resulting in a problem including a complicated process of attachment.

### SUMMARY OF THE INVENTION

An exemplary object of the present invention is to address these problems. In other words, the object of the present invention includes: actualizing an insulating process with ease and without waste by mounting an insulating film having functionality such as heat-resistance in order to insulate the surface of an object to be insulated; enabling easy attachment to be processed with stability after the attachment even for an object with concave or convex portions in the surface to be insulated; and avoiding excessive weight of the object to be insulated after the insulating process.

In order to accomplish the aforementioned and other objects, a heat-resistant insulating film and an insulating method according to the present invention comprise at least one of features described below.

According to one aspect of the present invention, there is provided a heat-resistant insulating film comprising a pattern profile corresponding to a structure with geometries including a convex or concave portion, wherein the pattern profile is formed by three-dimensional forming for fitting onto the structure.

According to another aspect of the present invention, there is provided a method for insulating a structure to be insulated, comprising the steps of forming a heat-resistant insulating film into a pattern profile corresponding to a surface to be insulated of the structure with geometries including a convex or concave portion by three-dimensional forming, and covering the surface to be insulated with the heat-resistant insulating film.

### BRIEF DESCRIPTION OF DRAWINGS

These and other objects and advantages of the present invention will become clear from the following description with reference to the accompanying drawings, wherein:

FIGS. 1A to 1D illustrate forming the pattern profile of the heat-resistant insulating film by the vacuum/compressed air forming according to an example of the present invention;

FIGS. 2A to 2E illustrate forming the pattern profile of the heat-resistant insulating film by the vacuum/compressed air forming according to another example of the present invention;

FIGS. 3A and 3B illustrate forming the pattern profile of the heat-resistant insulating film by the vacuum/compressed air forming according to yet another example of the present invention;

FIGS. 4A to 4C illustrate forming the pattern profile of the heat-resistant insulating film by the vacuum/compressed air forming according to a further example of the present invention;

FIGS. 5A to 5D illustrate forming the pattern profile of the heat-resistant insulating film by the vacuum/compressed air forming according to a still further example of the present invention;

FIG. 6 illustrates a frame used in the vacuum/compressed air forming according to the examples;

FIG. 7 illustrates an application of the heat-resistant insulating film according to the examples to a circuit board;

FIG. 8 illustrates an application of the heat-resistant insulating film according to the examples to a motor core; and

FIG. 9 illustrates another application of the heat-resistant insulating film according to the examples to the motor core.

### DETAILED DESCRIPTION OF THE PREFERRED EMBODIMENTS

A preferred embodiment of the present invention will herein after be described. A heat-resistant insulating film according to the embodiment is a film of resin with heat-resistance such as polyimide resins. Exemplary materials for the film are polyimide, polyamide, polybenzimidazole, polyester, polyimidazole, polyphenylenesulfide, polyamideimide, polyetherimide, polyethelketone, and polysulphon.

In order to mount such a heat-resistant insulating film on a structure with a profile including concave or convex portions, a pattern profile (hereinafter referred to as uneven pattern profile) corresponding to the profile of the structure, is formed by three-dimensional forming. This formation allows the heat-resistant insulating film to be mounted readily on an object to be insulated, and also enables stable attachment even on an object to be insulated with an uneven surface profile. It should be noted that the uneven pattern profile has a ratio of the depth to the opening width less than or equal to two. This feature enables formation of the pattern profile even for heat-resistant films with less formability.

When a circuit board mounted with electronic components is adopted as a structure of an object to be insulated, a heat-resistant insulating film three-dimensionally formed in accordance with the profile of the structure is utilized, considering the electronic components characterizing convex portions with respect to the circuit board. The utilization of this film readily actualizes a stable insulating cover with heat-resistance.

Such an even heat-resistant insulating film can be three-dimensionally formed by vacuum/compressed air forming. That is, the heat-resistant insulating film is formed into the uneven pattern profile by dragging the even heat-resistant insulating film into concave portions of a die using vacuum or compressed air. It should be noted that the die might be subjected to heat as required.

The heat-resistant insulating film can also be three-dimensionally formed by pressure forming. According to this pressure forming, the heat-resistant insulating film is formed into the uneven pattern profile by pressing the heat-resistant insulating film into concave portions of a die. It should be noted that the die might be subjected to heat as required.

An insulating method utilizing this heat-resistant insulating film includes forming the heat-resistant insulating film into the uneven pattern profile in accordance with the surface of the object to be insulated, and covering the object to be insulated such as electronic components and a circuit board with the uneven heat-resistant insulating film.

The heat-resistant insulating film and the insulating method according to this embodiment enables an insulating process providing high functionality by mounting the insulating film having heat-resistance to insulate the surface of the object to be insulated. Further, the insulation is attained only by mounting the film, thereby enabling a low-cost and easy process. Moreover, the three-dimensional formation of the pattern profile corresponding to the profile of the surface to be insulated actualizes easy mounting and stability after the mounting even for the object to be insulated having concave or convex portions in its surface to be insulated. And, the insulation by mounting the lightweight film does not increase the weight of the object to be insulated in contrast to the insulation by filling the surface to be insulated with a resin.

### EXAMPLES

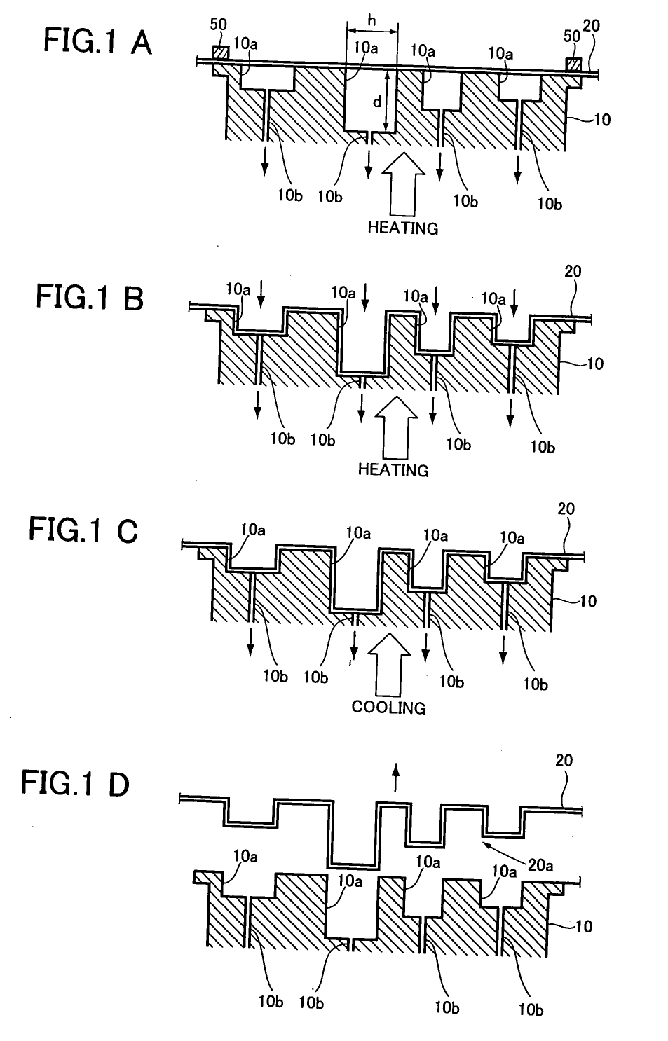

Examples according to the present invention will hereinafter be described with reference to the accompanying drawings. FIGS. 1A to 1D illustrate forming a pattern profile of the heat-resistant insulating film by the vacuum/compressed air forming. Grooves 10a corresponding to the uneven pattern profile of the object to be insulated are formed on a die 10 for forming the uneven pattern profile. The groove 10a having the width h and the depth d is formed so as to satisfy an inequality d/h≦2. Ventilating ducts 10b opening to the respective grooves 10a are formed in the die 10.

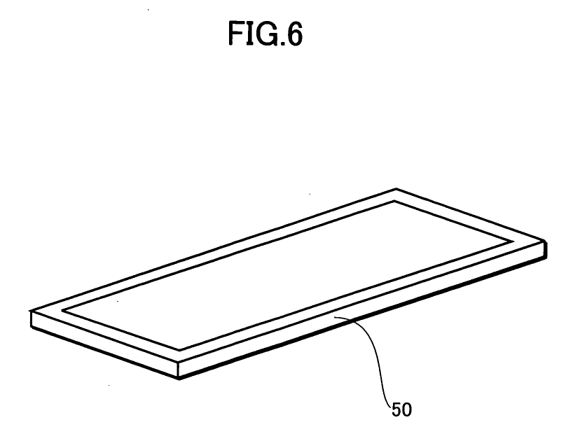

Each of processes is now sequentially described according to the pattern formation of the present example. First, as shown in FIG. 1A, the heat-resistant insulating film (polyimide film) 20 as an object to be formed is placed on the die 10. Then, a frame 50 shown in FIG. 6 is downwardly pressed against the die 10 to hold the heat-resistant insulating film 20 at its rim between the die 10 and the frame 50.

A process shown in FIG. 1B forms the uneven pattern profile by pressing the heat-resistant insulating film 20 against the grooves 10a of the die 10. In other words, pressurization applied as required from above and suction through the ventilating ducts 10b drag the heat-resistant insulating film 20 into the grooves 10a, thereby forming the heat-resistant insulating film 20 into the uneven pattern profile. At this process, the die 10 is optionally subject to heating as required. The heating ensures the formation of the uneven pattern profile.

After the completion of the forming process, the die 10 is cooled as shown in FIG. 1C in case of necessity. The cooling hardens the heat-resistant insulating film 20 having been softened by heating, thereby maintaining the formed uneven pattern profile. Subsequently, as shown in FIG. 1D, the heat-resistant insulating film 20 is released from the die 10, thereby providing the heat-resistant insulating film 20 formed into the desired uneven pattern profile 20a.

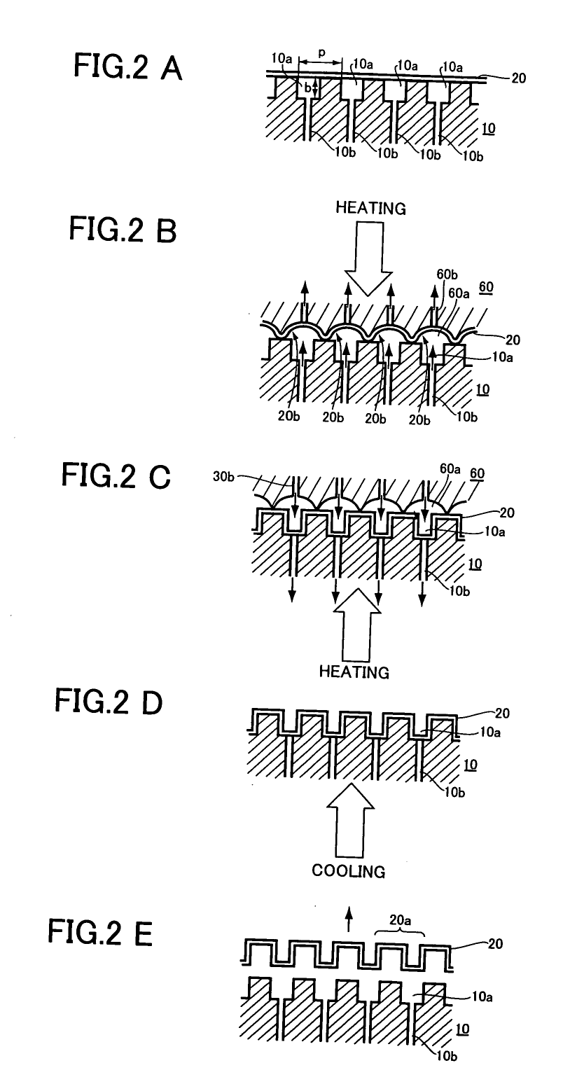

FIG. 2 illustrates forming a pattern profile of the heat-resistant insulating film by the vacuum/compressed air forming according to another example. Since, in this example, processes shown in FIGS. 2A, 2D and 2E are similar to the respective processes shown in FIGS. 1A, 1C and 1D, the redundant description is omitted.

In this example, a preforming die 60, which has an uneven pattern profile corresponding to that of the die 10, is further provided on the heat-resistant insulating film 20. The preforming die 60 has concave portions 60a formed so as to correspond to the grooves 10a in one-to-one relationship. The concave portions 60a forms the uneven pattern profile corresponding to a profile of the preforming die 60. The preforming die 60 also has ventilation ducts 60b formed so as to correspond to the respective concave portions 60a.

In the process shown in FIG. 2B, the preforming die 60 forms preliminary portions 20b corresponding to the pattern profile of the die 10 on the heat-resistant insulating film 20. In other words, the suction through the ventilating ducts 60b in the preforming die 60 and/or pressurization through the ventilating ducts 10b in the die 10 drags the heat-resistant insulating film 20 into the concave potions 60a, thereby forming the preliminary portions 20b corresponding to the pattern profile of the concave portions 60a on the heat-resistant insulating film 20. At this process, the preforming die 60 is optionally subject to heating as required. The heating of the preforming die 60, in the preforming process, also serves as preliminary heating for the subsequent forming, and thus can effectively perform the performing process.

In the process shown in FIG. 2C, the aforementioned preliminary portions 20b are pressed against the uneven pattern profile of the die 10 to form the heat-resistant insulating film 20 into the corresponding uneven pattern profile. That is, in the forming process, the pressurization through the ventilating ducts 60b in the preforming die 60 and/or the suction through the ventilating ducts 10b in the die 10 drags the preliminary portions 20b into the grooves 10a, thereby forming the heat-resistant insulating film 2O into the uneven pattern profile 20a corresponding to the grooves 10a. At this process, the die 10 is optionally subject to heating as required. The heating ensures the formation of the uneven pattern profile 20a.

Subsequent processes shown in FIGS. 2D and 2E are similar to those shown in FIGS. 1C and 1D, and produces the heat-resistant insulating film 20 with uneven pattern profile 20a.

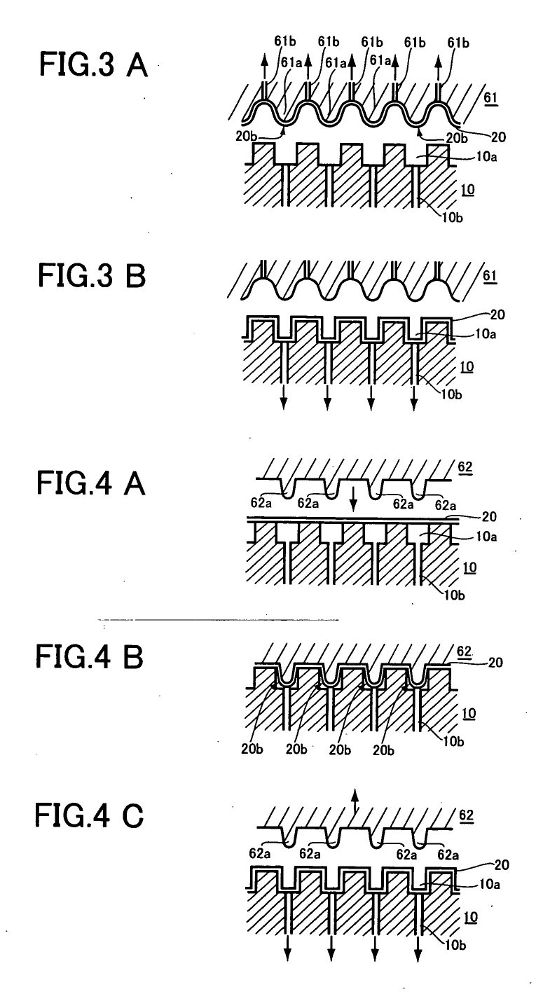

FIGS. 3A and 3B illustrate a method for forming a pattern profile according to yet another example. In this example, identical portions with the aforementioned example are indicated by the same reference symbols to omit the redundant description. In this example, a preforming die 61 is utilized which has convex portions 61a corresponding to the grooves 10a characterizing the pattern profile of the die 10. The preforming die 61 also has ventilating ducts 61b for dragging the heat-resistant insulating film 20 onto the preforming die 61.

Each of processes is now sequentially described according to the pattern formation of this example. First, as shown in FIG. 3A, the heat-resistance insulating film 20, which is an object to be formed, is provided on the die 10, and then the preforming die 61 is further provided thereon. In this preforming process, the suction is performed through the ventilating ducts 61b in the preforming die 61, thereby pressing the heat-resistant insulating film 20 against the preforming die 61. Since the preforming die 61 has convex portions 61a formed thereon so as to correspond to the grooves 10a in the die 10 in one-to-one relationship, the convex portions 61a forms the preliminary portions 20b corresponding to the pattern profile of the die 10 onto the heat-resistant insulating film 20. At this process, the preforming die 61 may be optionally subject to heating as required. The heating of the preforming die 61, in the preforming process, also serves as preliminary heating for the subsequent forming, and thus effectively enables to perform the preforming process.

In the process shown in FIG. 3B, the suction through the ventilating ducts 10b in the die 10 drags the preliminary portions 20b into the grooves 10a, thereby forming the heat-resistant insulating film 20 into the uneven pattern profile 20a corresponding to the grooves 10a. At this process, the die 10 is optionally subject to heating as required. The heating ensures the formation of the pattern profile. Subsequently, cooling is performed as required in a similar manner to that of the aforementioned example, and then the heat-resistant insulating film 20 is released from the die 10, thereby producing the heat-resistant insulating film 20 formed into the uneven pattern profile.

FIGS. 4A to 4C illustrate a further method for forming a pattern profile according to the other example. In this example, identical portions with the aforementioned examples are indicated by the same reference symbols to omit the redundant description. In this example, a preforming die 62 is utilized which has convex portions 62a corresponding to the grooves 10a in one-to-one relationship. The preforming die 62 is pressed onto the heat-resistant insulating film placed on the die 10 (see FIG. 4A), thereby preliminary portions 20b of the heat-resistant insulating film 20 are formed in the respective grooves 10a of the die 10 (see FIG. 4B) . Then, the preforming die 62 is released, and then the suction is applied through the ventilating ducts 10b in the die 10 to the heat-resistant insulating film 20 to drag the preliminary portions 20b formed in the grooves 10a onto the inner surfaces of the grooves 10a, thereby forming the heat-resistant insulating film 20 into the uneven pattern profile corresponding to the grooves 10a. At this process, the die 10 is optionally subject to heating as well as in the case with the aforementioned examples. Subsequently, cooling is performed as required in a similar manner to that of the aforementioned example, and then the heat-resistant insulating film 20 is released from the die 10, thereby producing the heat-resistant insulating film 20 formed into the uneven pattern profile.

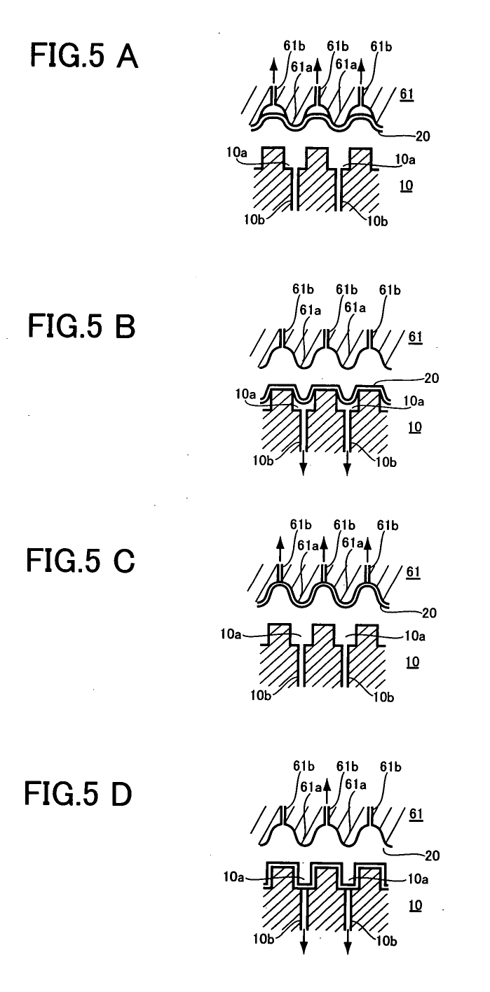

FIGS. 5A to 5D illustrate a method for forming a pattern profile according to a still further example. In this example, identical portions with the aforementioned examples are indicated by the same reference symbols to omit the redundant description. In this example, the preforming process and the forming process as illustrated in the above examples are alternately repeated. According to the example shown in FIGS. 5A to 5D, the processes of the example shown in FIGS. 3A and 3B are repeated.

In the preforming process shown in FIG. 5A, the suction through the ventilating ducts 61b in the preforming die 61 forms partial preliminary portions on the heat-resistant insulating film 20. Subsequently, as shown in FIG. 5B, the partially preliminary portions are dragged into the grooves 10a to be expanded. Then, as shown in FIG. 5C, the suction from the preforming die 61 forms the preliminary portions corresponding to the convex portions 61a of the preforming die 61. Finally, as shown in FIG. 5D, the suction from the die 10 drags the preliminary portions into the grooves 10a, thereby forcing the preliminary portions into contact with the inner surfaces of the grooves 10a. The repeated processes maybe further repeated multiple times in stages. Then, subsequent processes similar to the above examples are performed to form the heat-resistant insulating film 20 into the uneven pattern profile.

It should be noted that in the examples shown in FIGS. 2A to 5D the formation of the pattern profile is performed using the frame 50 as shown in FIG. 6 such that the die 10 holds the heat-resistant insulating film 20 at its rim.

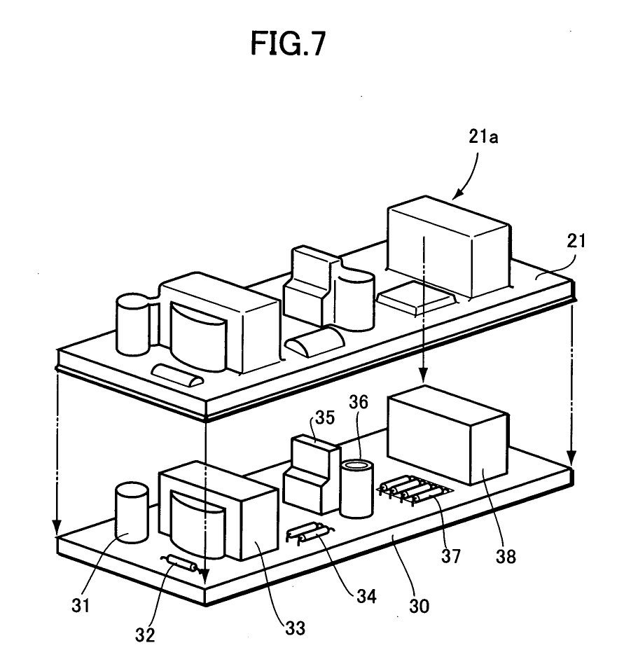

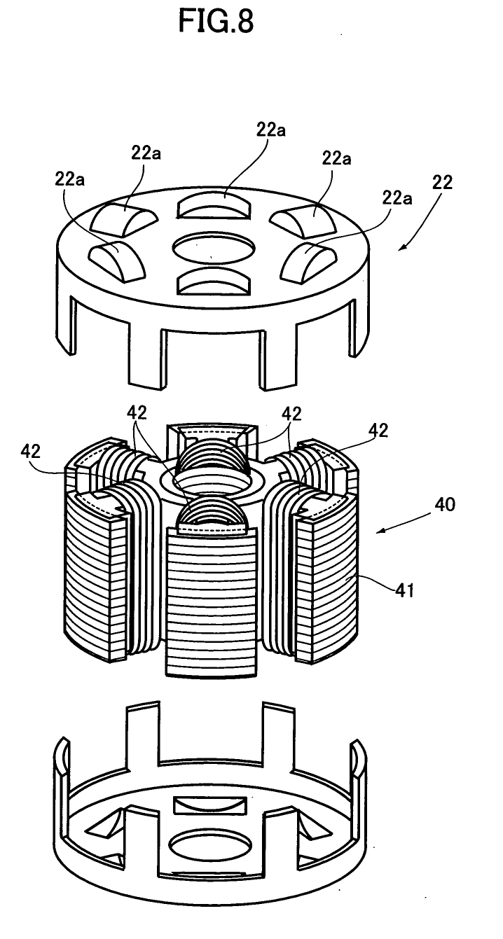

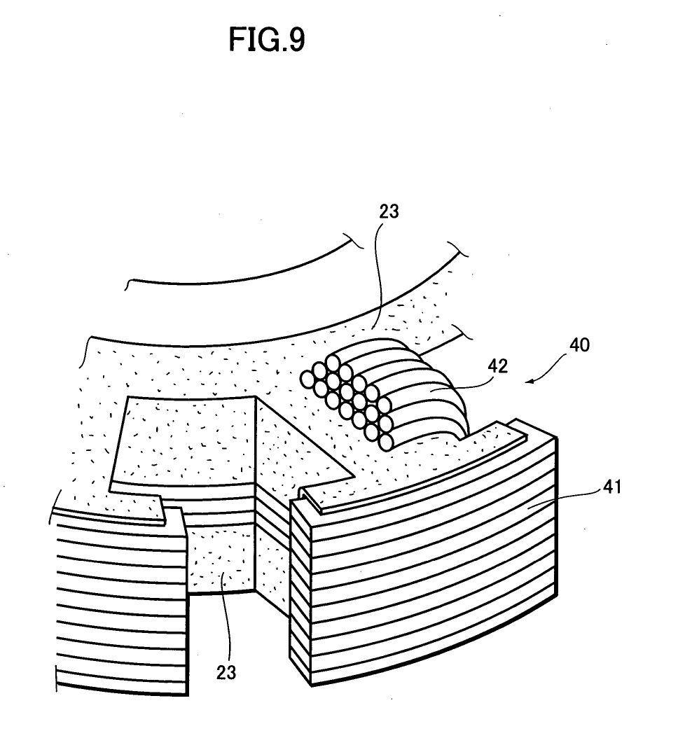

FIGS. 7 to 9 illustrate applications of the heat resistant film according to some examples. This heat-resistant insulating film 20 is utilized as a protective cover for portions requiring insulation and to be exposed to high temperature. FIG. 7 illustrates an application to insulation on a circuit board mounted with electronic components. FIGS. 8 and 9 illustrate applications for insulation on a motor core.

In the example shown in FIG. 7, various kinds of electronic components 31-38 are mounted on a circuit board 30. The electronic components 31-38 characterize the uneven pattern profile of the surface of the circuit board 30. Corresponding to the uneven pattern profile, the aforementioned grooves 10a are formed on the die 10, and the die 10 forms the heat-resistant insulating film 21 so as to cover the convex or concave profile of the electronic components. This formation can attain the heat-resistant insulating film 21 with the three-dimensionally formed uneven pattern profile 21a.

Then, the heat-resistant insulating film 21 is mounted on the circuit board 30 so as to cover the electronic components 31-38, thereby allowing the electronic components 31-38 and circuit board 30 to be insulated and covered with the high functionality heat-resistant insulating film 21 such as a polyimide film. This insulation enables weight reduction and space saving of the circuit board in comparison with the insulation by covering all of the electronic components with a resin, and is effective in implementation for continued downsizing and slimed down electronic devices.

FIG. 8 illustrates an example where a motor core is covered with a heat-resistant insulating film 22 at its upper surface and undersurface. The motor core 40 has a structure including an iron-core 41 and winding of wire 42 wound thereon. Convex portions made of the winding of the wire 42 are formed on the upper surface and the under surface of the motor core 40. A convex pattern profile 22a complementarily corresponding to the convex portions is formed, and three-dimensional structure corresponding to that of the iron-core is formed. Then, the formed pattern profile is fitted to the upper surface and the undersurface of the motor core 40.

FIG. 9 illustrates an example where a heat-resistant insulating film 23 is fitted directly onto the surface of the iron-core 41 of the motor core 40. In this case, the heat-resistant insulating film 23 is formed corresponding to the three-dimensional pattern profile of the iron-core 41, the heat-resistant insulating film 23 is first mounted, and then the wire 42 is wound thereon.

According to these examples, the mounting of an insulating film having functionality such as heat-resistance in order to insulate the surface of an object to be insulated enables the easy and low-cost insulating process. This insulating process also provides easy mounting and stability after the mounting even for an object with concave and convex portions in its surface to be insulated. Further, the insulation can be attained only by mounting the lightweight film, thereby reducing the weight of components or devices in comparison with resin molding.

While the presently preferred embodiments of the present invention have been shown and described, it is to be understood that these disclosures are for the purpose of illustration and that various changes and modifications may be made without departing from the scope of the invention as set forth in the appended claims.

What is claimed is:

1. A heat-resistant insulating film, comprising:
a pattern profile corresponding to a structure with geometries including a convex or concave portion, the pattern profile being formed by three-dimensional forming for fitting onto the structure.

2. The heat-resistant insulating film according to claim 1, wherein a material of the film is a polyimide.

3. The heat-resistant insulating film according to claim 1, wherein the pattern profile includes an uneven profile having a ratio of a depth to an opening width less than or equal to two.

4. The heat-resistant insulating film according to claim 1, wherein the structure is a circuit board mounted with electronic components on the board.

5. The heat-resistant insulating film according to claim 1, wherein the three-dimensional forming is vacuum/compressed air forming.

6. The heat-resistant insulating film according to claim 1, wherein the three-dimensional forming is pressure forming using a die.

7. A method for insulating a structure to be insulated, comprising:
forming a heat-resistant insulating film into a pattern profile corresponding to a surface to be insulated of the structure with geometries including a convex or concave portion by three-dimensional forming; and
covering the surface to be insulated with the heat-resistant insulating film.

8. The method according to claim 7, wherein a material of the film is a polyimide.

9. The method according to claim 7, wherein the pattern profile includes an uneven profile having a ratio of a depth to an opening width less than or equal to two.

10. The method according to claim 7, wherein the structure is a circuit board mounted with electronic components on the board.

11. The method according to claim 7, wherein the three-dimensional forming is vacuum/compressed air forming.

12. The method according to claim 7, wherein the three-dimensional forming is pressure forming using a die.
